(19) United States
(12) Patent Application Publication
(10) Pub. No.: US 2013/0015539 A1
(43) Pub. Date: Jan. 17, 2013

(54) MAGNETIC MEMORY DEVICE HAVING INCREASED MARGIN IN THICKNESS OF MAGNETIC LAYERS

(71) Applicant: Won Joon CHOI, Ichon-si (KR)

(72) Inventor: Won Joon CHOI, Ichon-si (KR)

(21) Appl. No.: 13/240,689

(22) Filed: Sep. 22, 2011

(30) Foreign Application Priority Data
Jul. 13, 2011 (KR) 10-2011-0069625

(51) Int. Cl. H01L 29/82

(52) U.S. Cl. 257/421; 257/E29.323

(57) ABSTRACT

A magnetic memory device capable of ensuring a constant TMR difference even when the margin in a thickness of a magnetic layer constituting a KO is small is provided. The magnetic memory device includes a first magnetic layer having a fixed magnetization direction, a magnetization fixing layer formed on the first magnetic layer, a tunnel barrier layer formed on the magnetization fixing layer, and a second magnetic layer formed on the tunnel barrier layer and having a changeable magnetization direction.

### CROSS-REFERENCES TO RELATED APPLICATION

The present application claims priority under 35 U.S.C. 119(a) to Korean application number 10-2011-0069625, filed on Jul. 13, 2011, in the Korean Patent Office, which is incorporated by reference in its entirety as if set forth in full.

### BACKGROUND OF THE INVENTION

1. Technical Field

The present invention relate to a semiconductor integrated circuit device, and more particularly, to a magnetic memory device having an increased margin in thicknesses of magnetic layers.

2. Related Art

Along with high operation speed and low power consumption, a fast write/read operation and a low operation voltage are also useful characteristics of memory devices embedded in the electronic appliance. Magnetic memory devices have been suggested to satisfy the useful characteristics. The magnetic memory devices may have high speed operation and/or non volatile characteristics.

In general, magnetic memory devices may include magnetic tunnel junctions (hereinafter, referred to as MTJs). The MTJ may include a pair of magnetic layers and an insulating layer constituted of an insulating material and interposed between the pair of magnetic layers. A resistance of the MTJ may change based on magnetization directions of the pair of magnetic layers.

For example, when the magnetization directions of two magnetic layers are anti-parallel to each other, the resistance of the MTJ is “high” and when the magnetization directions of two magnetic layers are parallel to each other, the resistance of the MTJ is “low”. Therefore, the MJT may have different resistances, and it is possible to read/write data according to a resistance difference.

Tunnel magnetroresistance (TMR) is a parameter which decides characteristics of the MTJ and the two magnetic layers constituting the MTJ may have a certain difference in their thicknesses to ensure the stable characteristics of the MTJ.

However, like a semiconductor memory device, an integration density of the magnetic memory device may be increased so that it may be difficult to ensure a margin of 10 Å or more in thicknesses of the two magnetic layers.

Further, although the MTJ is designed to ensure the above margin, the margin may be more reduced in a manufacturing process and thus a desirable TMR difference between the two magnetic layers may not occur. Therefore, an operation of the TMJ may not be properly performed.

### SUMMARY

Exemplary embodiments of the present invention provide a magnetic memory device capable of ensuring a constant tunnel magnetroresistance (TMR) difference between magnetic layers constituting a magnetic tunnel junction (MTJ) in a relatively small margin in a thickness of the magnetic layers.

According to one aspect of an exemplary embodiment, a magnetic memory device includes a first magnetic layer having a fixed magnetization direction, a magnetization fixing layer formed on the first magnetic layer, a tunnel barrier layer formed on the magnetization fixing layer, and a second magnetic layer formed on the tunnel barrier layer and having a changeable magnetization direction.

According to another aspect of an exemplary embodiment, a magnetic memory device includes a semiconductor substrate, a first electrode line formed on the semiconductor substrate, a lower buffer layer formed on the first electrode line, a first magnetic layer formed on the lower buffer layer and having a fixed magnetization direction, a magnetization reinforcement layer formed on the first magnetic layer and increasing a magnetizing force of the first magnetic layer, a diffusion blocking layer formed on the magnetization reinforcement layer and blocking diffusion of components of the magnetization reinforcement layer, a tunnel barrier layer formed on the diffusion blocking layer, a second magnetic layer formed on the tunnel barrier layer, an upper buffer layer formed the second magnetic layer, and a second electrode line formed on the upper buffer layer.

According to still another aspect of an exemplary embodiment, a magnetic memory device includes a first MTJ constituting of a fixing magnetic layer, a fixing reinforcement layer, a diffusion block layer, a tunnel barrier layer, and a free magnetic layer stacked, an insulating layer formed on the first MTJ, and a second MTJ formed on the insulating layer.

These and other features, aspects, and embodiments are described below in the section entitled “DESCRIPTION OF EXEMPLARY EMBODIMENT”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a perspective view of a magnetic memory device according to an exemplary embodiment of the present invention;

FIGS. 2A to 2D are cross-sectional views of magnetic tunnel junctions of the magnetic memory device according to exemplary embodiments of the present invention;

FIGS. 3 to 5 are cross-sectional views of magnetic memory devices having the magnetic tunnel junction shown in FIG. 2D according to exemplary embodiments of the present invention;

FIGS. 6 to 7 are cross-sectional views of stacked magnetic tunnel junctions according to exemplary embodiments of the present invention; and

FIG. 8 is a graph illustrating a relationship of resistance versus magnetic field, where a spin behavior characteristic illustrates a magnetization of the magnetic tunnel junction depending on a magnetic field when a magnetization fixing layer is interposed according to exemplary embodiment of the present invention.

### DESCRIPTION OF EXEMPLARY EMBODIMENT

Exemplary embodiments are described herein with reference to cross-sectional views of exemplary embodiments (and intermediate structures). However, proportions and shapes illustrated in the drawings are exemplary only and may vary depending on various manufacturing techniques and/or design considerations. In parts of the drawings, lengths and sizes of layers and regions of exemplary embodiments may be exaggerated for clarity in illustration. Throughout the drawings, like reference numerals denote like elements. Throughout the disclosure, when a layer is referred to as being “on” another layer or substrate, it can be directly on the other layer or substrate, or intervening layers may also be present.

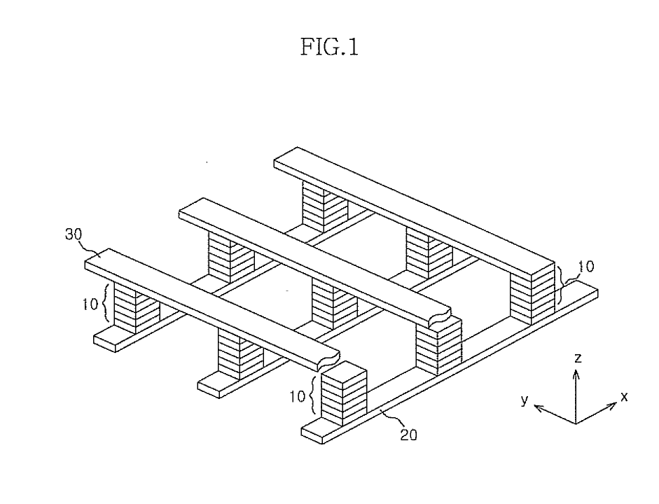

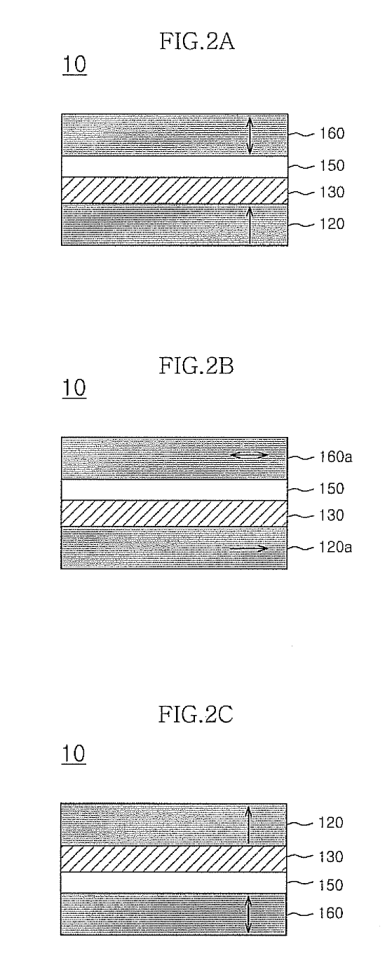

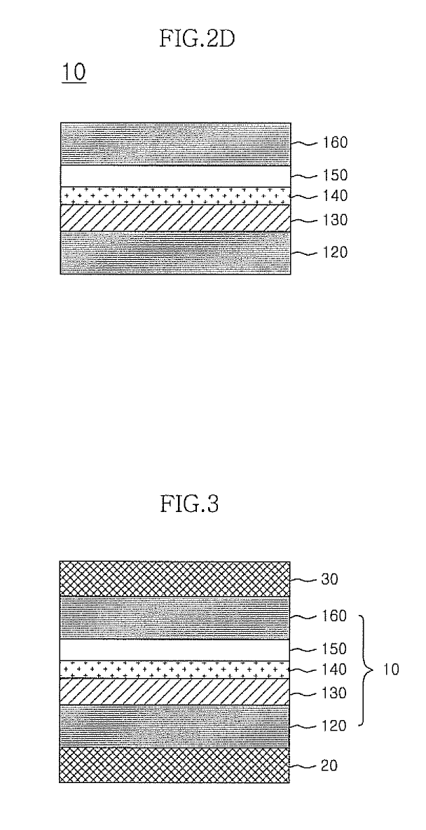

FIG. 1 is a perspective view illustrating a magnetic memory array according to an exemplary embodiment and FIG. 2A is a cross-sectional view illustrating a magnetic tunnel junction (MTJ) of the magnetic memory array according to an exemplary embodiment.

Referring to FIG. 1, the MTJs 10 are connected between a plurality of word lines 20 and a plurality of bit lines 30. The plurality of word lines 20 may extend in an X-direction of FIG. 1 and the plurality of bit lines 30 may extend in a Y-direction of FIG. 1. The MTJs 10 are disposed at intersections of the plurality of word lines 20 and the plurality of bit lines 30.

As shown in FIG. 2A, the MTJ 10 may include a first magnetic layer 120, a magnetization fixing layer 130, a tunnel barrier layer 150, and a second magnetic layer 160.

The first magnetic layer 120 is a magnetic layer of which a magnetization direction is fixed and may have an out-of-plane (perpendicular) magnetic anisotropy. The first magnetic layer 120 is separated from the second magnetic layer 160 by the tunnel barrier layer 150. That is, a magnetization direction of the first magnetic layer 120 is perpendicular to a surface thereof. Although the first magnetic layer 120 includes, for example, a material of CoFeB, it is not limited thereto and various magnetic substances may be used.

The magnetization fixing layer 130 is interposed between the first magnetic layer 120 and the tunnel barrier layer 150 to control a spin behavior of the first magnetic layer 120. The magnetization fixing layer 130 serves to adjust a range of a magnetic field which reverses the magnetization direction of the first magnetic layer 120. For example, since the magnetization fixing layer 130 is coupled to the first magnetic layer 120, the magnetization fixing layer 130 increases a critical value of a magnetic field in which a magnetization direction of the first magnetic layer 120 starts to be reversed. Therefore, it is not necessary to increase an intensity of a magnetization current for reversing the magnetization.

The first magnetic layer 120 maintains a constant magnetic resistance so that although a thickness of the first magnetic layer 120 may be reduced, the first magnetic layer 120 may maintain a constant coercive force by the magnetization fixing layer 130. The magnetization fixing layer 130 may be referred to as a magnetization reinforcement layer. The magnetization fixing layer 130 may include a manganese (Mn) alloy material, for example, a PtMn layer or a FeMn layer.

When the magnetization fixing layer 130 is formed on a surface of the first magnetic layer 120 opposite to that of the second magnetic layer 160, characteristics of the magnetization fixing layer 130 become better. The difference of a coercive force between the first magnetic layer 120 and the second magnetic layer 160 is significant for the MTJ 10 to properly operate. As described above, the magnetization fixing layer 130 may be arranged on a surface of the first magnetic layer 120 substantially facing the surface of the second magnetic layer 160. That is, since the magnetization fixing layer 130 may fix the magnetization direction of the first magnetic layer 120 although a magnetization direction of the second magnetic layer 160 is changed, it may be possible to mitigate the phenomenon that the magnetization direction is reversed and to improve characteristics of the magnetization fixing layer 130 as compared with when the magnetization fixing layer 130 is disposed on the bottom of the first magnetic layer 120.

The tunnel barrier layer 150 is disposed between the magnetization fixing layer 130 and the second magnetic layer 160. The tunnel barrier layer 150 may include an insulating layer or a semiconductor layer. The insulating layer may include at least one selected from the group consisting of magnesium oxide (MgO), aluminum oxide (Al₂O₃), hafnium oxide (HfO₂), titanium oxide (TiO₂), yttrium oxide (Y₂O₃), and ytterbium oxide (Yb₂O₃).

The second magnetic layer 160 may formed on the tunnel barrier layer 150 and a magnetization direction thereof is changeable depending on a magnetic field applied thereto. In particular, the magnetization direction is reversed in response to the value of the magnetic field. Thereby, the second magnetic layer 160 may be referred to as a free magnetic layer.

As shown in FIG. 2B, a first magnetic layer 120a and a second magnetic layer 160a may be also formed to have in-plane (horizontal) magnetic anisotropy. That is, the first and second magnetic layers 120a and 160a have magnetization directions parallel to their surfaces.

Meanwhile, as shown in FIG. 2C, a second magnetic layer 160, a tunnel barrier layer 150, a magnetization fixing layer 130, and a first magnetic layer 120 may be sequentially stacked.

The MTJ shown in FIGS. 2A to 2C may further include an atom trapping layer. As shown in FIG. 2D, an atom trapping layer 140 may be further interposed between a tunnel barrier layer 150 and a magnetization fixing layer 130 shown in FIG. 2A. The atom trapping layer 140 includes a compound containing at least one of boron (B) and nitrogen (N) and blocks diffusion of a principal component of the magnetization fixing layer 130, for example, a Mn component, toward the tunnel barrier layer 150. Therefore, in the exemplary embodiment, a compound or an alloy material containing B or N is interposed as a diffusion blocking layer, i.e., the atom trapping layer 140, so that the diffusion of Mn component may be blocked by chemical bond. Further, the atom trapping layer 140 is disposed under the tunnel barrier layer 150 and blocks the Mn component diffusing into the tunnel barrier layer 150. The atom trapping layer 140 includes any one selected from the group consisting of CoPtB, CoPdB, FePtB, FePdB, CoFePtB, CoFePdB, CoPdN, CoPdN, FePtN, FePdN, CoFePtN, CoFePdN, CoPtBN, CoPdBN, FePtBN, FePdBN, CoFePtBN, CoFePdB, CoFeN, and CoFeBN.

Although the Mn metal compound has a characteristic raising a polarity of a magnetic layer by an exchange coupling with the magnetic layer, it is difficult to form the Mn metal compound adjacent to the tunnel barrier layer 150 since the Mn component diffuses at a high temperature of a heat treatment process. However, since the atom trapping layer 140 is additionally formed on the magnetization fixing layer 130 in the exemplary embodiment, the atom trapping layer 140 blocks the Mn component diffusing toward the tunnel barrier layer 150 and the second magnetic layer 160.

The atom trapping layer 140 having the N component increases a crystallographic orientation of a material forming the tunnel barrier layer 150 and further serves as a seed layer of the tunnel barrier layer 150.

When a CoFeBN layer is used for the atom trapping layer 140, the B component may escape from the combination in a heat treatment process. The escaping B component and the Mn component of the magnetization fixing layer 130 may be additionally combined within the atomic trapping layer 140 so that deformation of the crystal structure may be prevented.

The atom trapping layer 140 may be applied to the structures of FIGS. 2B and 2C as well as the structure of FIG. 2A.

FIG. 3 is a cross-sectional view of a magnetic memory device in which the MTJ 10 shown in FIG. 2D is interposed between a word line 20 and a bit line 30 of FIG. 1. Although a lower electrode line is referred to as the word line 20 and an upper electrode line is referred to as the bit line 30, the lower electrode line may be referred to as a bit line and the upper electrode line may be referred to as a word line. Meanwhile, the lower electrode line may be referred to as a lower electrode and the upper electrode line may be referred to as an upper electrode.

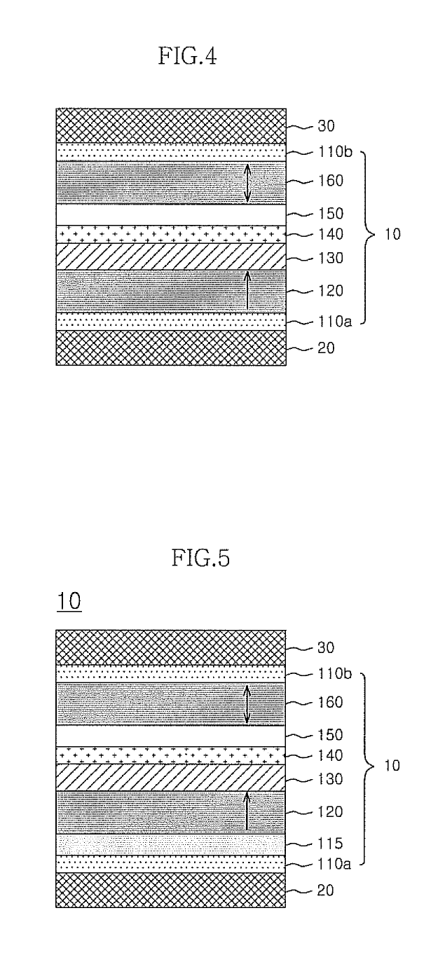

As shown in FIG. 4, a buffer layer 110a (or 110b) may be interposed between a word line 20 and a first magnetic layer 120 (or between a bit line 30 and a second magnetic layer 160). The buffer layers 110a and 110b may include gold (Au), ruthenium (Ru), tantalum (Ta), copper (Cu), copper nitride (CuN), palladium (Pd), platinum (Pt), or a diamond-like carbon material. The buffer layers 110a and 110b are formed as outer layers of a MTJ 10 so that the buffer layers 110a and 110b serve to bond the MTJ 10 to other devices.

Referring to FIG. 5, an antiferromagnetic layer 115 may be further interposed between a lower buffer layer 110a and a first magnetic layer 120. The antiferromagnetic layer 115 may be additionally disposed under the first magnetic layer 120 to strengthen magnetization of first magnetic layer 120.

FIG. 6 illustrates a stacked MTJ ‘MM’ according to another exemplary embodiment. Referring to FIG. 6, the stacked MTJ ‘VIM’ includes a first MTJ 10a and a second MTJ 10b stacked on the first MTJ 10a. The first MTJ 10a includes a lower buffer layer 110a, a first magnetic layer 120, a magnetization fixing layer 130, an atom trapping layer 140, a tunnel barrier layer 150, a second magnetic layer 160, and an upper buffer layer 110b sequentially stacked. The second MTJ 10b has the same stacking structure as the first MTJ 10a, An insulating layer 200 may be interposed between the first MTJ 10a and the second MTJ 10b and the first and second Mils 10a and 10b may have the same coercive force or different coercive forces from each other.

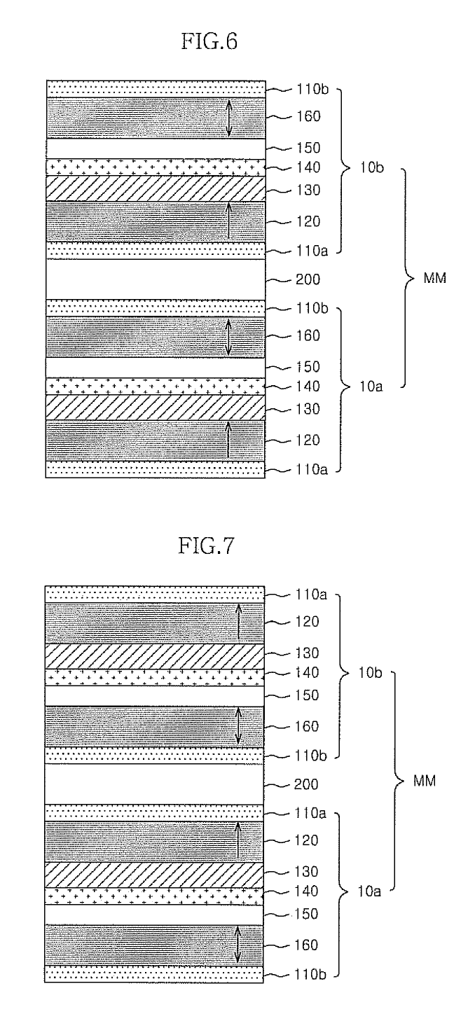

As shown in FIG. 7, a first MTJ 10a and a second MTJ 10b may be arranged in a symmetrical manner with an insulating layer 200 being interposed.

According to the above-described embodiments, the magnetization fixing layer 130 is disposed on the first magnetic layer 120. Therefore, an exchange bias is generated at a contact boundary between the first magnetic layer 120 and the magnetization fixing layer 130 so that a magnetization force is relatively strengthened on one surface of the first magnetic layer 120.

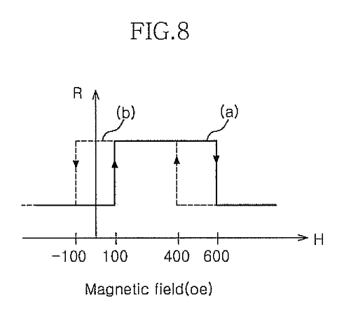

FIG. 8 is a graph showing a relationship of magnetic field H versus resistance R which illustrates a spin behavior characteristic, wherein (a) shows the case where a magnetization fixing layer is interposed and (b) shows the case where a magnetization fixing layer is not interposed in the related art.

Referring to FIG. 8, when the magnetization fixing layer 130 is interposed (the case (a)), the magnetism is increased as compared with the case (b) where the magnetization fixing layer is not interposed. That is, in the case (b), the magnetism is generated when relatively larger magnetic field is applied.

Therefore, by forming the magnetization fixing layer 130 on a surface of the first magnetic layer 120, the magnetism, that is, a coercive force of the first magnetic layer 120 is increased. Although there is little margin in thickness of the first and second magnetic layers 120 and 160, electric characteristics of the MTJ may be raised by increasing a threshold value of a magnetic field for a magnetization reversal of the first magnetic layer 120.

According to the exemplary embodiment, by forming the atom trapping layer 140 on the magnetization fixing layer 130, diffusion of materials constituting the magnetization fixing layer 130 may be prevented so that electric characteristics and crystallographic orientation of the tunnel barrier layer 140 may be raised.

While certain embodiments have been described above, it will be understood that the embodiments described are by way of example only. Accordingly, the present invention should not be limited to the specific disclosed embodiments, claims should be broadly interpreted to include all reasonably suitable embodiments consistent with the exemplary embodiments.

What is claimed is:

1. A magnetic memory device, comprising:
a first magnetic layer having a fixed magnetization direction;
a magnetization fixing layer formed on the first magnetic layer;
a tunnel barrier layer formed on the magnetization fixing layer; and
a second magnetic layer formed on the tunnel barrier layer and having a changeable magnetization direction.

2. The magnetic memory device of claim 1, wherein the magnetization fixing layer includes a manganese (Mn) alloy material.

3. The magnetic memory device of claim 2, wherein the magnetization fixing layer includes PtMn or FeMn.

4. The magnetic memory device of claim 1, further comprising an atom trapping layer formed between the magnetization fixing layer and the tunnel barrier layer and blocking diffusion of components of the magnetization fixing layer.

5. The magnetic memory device of claim 4, wherein the magnetization fixing layer includes an alloy material containing manganese (Mn) as the component and the atom trapping layer includes an alloy material containing boron (B), nitrogen (N), or boron nitride (BN) as a component.

6. The magnetic memory device of claim 5, wherein the atom trapping layer includes any one selected from the group consisting of CoPtB, CoPdB, FePtB, FePdB, CoFePtB, CoFePdB, CoPtN, CoPdN, FePtN, FePdN, CoFePtN, CoFePdN, CoPtBN, CoPdBN, FePtBN, FePdBN, CoFePtBN, CoFePdB, CoFeN, and CoFeBN.

7. The magnetic memory device of claim 1, wherein the tunnel barrier layer includes at least one selected from the group consisting of magnesium oxide (MgO), aluminum oxide (Al₂O₃), hafnium oxide (HfO₂), titanium oxide (TiO₂), yttrium oxide (Y₂O₃), and ytterbium oxide (Yb₂O₃).

8. The magnetic memory device of claim 1, wherein the first and second magnetic layers includes materials having out-of-plane magnetic anisotropy with respect to a surface of the first magnetic layer.

9. The magnetic memory device of claim 8, wherein the first and second magnetic layers includes a CoFeB.

10. The magnetic memory device of claim 1, wherein the first and second magnetic layers includes materials having in-plane magnetic anisotropy with respect to a surface of the first magnetic layer.

11. The magnetic memory device of claim 1, further comprising:
a first electrode line electrically connected to a bottom of the first magnetic layer; and
a second electrode line electrically connected to a top of the second magnetic layer.

12. The magnetic memory device of claim 11, further comprising:
a lower buffer layer interposed between the first electrode line and the first magnetic layer; and
an upper buffer layer interposed between the second electrode line and the second magnetic layer.

13. The magnetic memory device of claim 12, wherein the lower and upper buffer layers include any one selected from the group consisting of gold (Au), ruthenium (Ru), tantalum (Ta), copper (Cu), copper nitride (CuN), palladium (Pd), and platinum (Pt).

14. The magnetic memory device of claim 12, further comprising an antiferromagnetic layer interposed between the lower buffer layer and the first magnetic layer.

15. A magnetic memory device, comprising:
a semiconductor substrate;
a first electrode line formed on the semiconductor substrate;
a lower buffer layer formed on the first electrode line;
a first magnetic layer formed on the lower buffer layer and having a fixed magnetization direction;
a magnetization reinforcement layer formed on the first magnetic layer and increasing a magnetizing force of the first magnetic layer;
a diffusion blocking layer formed on the magnetization reinforcement layer and blocking diffusion of components of the magnetization reinforcement layer;
a tunnel barrier layer formed on the diffusion blocking layer;
a second magnetic layer formed on the tunnel barrier layer;
an upper buffer layer formed on the second magnetic layer; and
a second electrode line formed on the upper buffer layer.

16. The magnetic memory device of claim 15, wherein the first and second electrode lines are disposed to cross each other.

17. The magnetic memory device of claim 15, wherein the magnetization reinforcement layer includes PtMn or FeMn.

18. The magnetic memory device of claim 17, wherein the diffusion blocking layer includes any one selected from the group consisting of CoPtB, CoPdB, FePtB, FePdB, CoFePtB, CoFePdB, CoPtN, CoPdN, FePtN, FePdN, CoFePtN, CoFePdN, CoPtBN, CoPdBN, FePtBN, FePdBN, CoFePtBN, CoFePdB, CoFeN, and CoFeBN.

19. The magnetic memory device of claim 18, wherein the diffusion blocking layer including nitrogen (N) serves as a seed layer of the tunnel barrier layer to increase crystal orientation of the tunnel barrier layer.

20. The magnetic memory device of claim 15, wherein the first and second magnetic layers includes materials having out-of-plane magnetic anisotropy with respect to a surface of the first magnetic layer.

21. The magnetic memory device of claim 20, wherein the first and second magnetic layers include CoFeB.

22. The magnetic memory device of claim 15, further comprising an antiferromagnetic layer interposed between the lower buffer layer and the first magnetic layer.

23. A magnetic memory device, comprising:
a first magnetic tunnel junction (MTJ) including a fixed magnetic layer, a magnetization reinforcement layer, a diffusion block layer, a tunnel barrier layer, and a free magnetic layer stacked;
an insulating layer formed on the first MTJ; and
a second MTJ formed on the insulating layer.

24. The magnetic memory device of claim 23, wherein the second MTJ has the same structure as the first MTJ.

25. The magnetic memory device of claim 23, wherein the first and second MTJs are symmetrically disposed with respect to the insulating layer.

26. The magnetic memory device of claim 25, wherein the magnetization reinforcement layer includes PtMn or FeMn.

27. The magnetic memory device of claim 26, wherein the diffusion blocking layer includes any one selected from the group consisting of CoPtB, CoPdB, FePtB, FePdB, CoFePtB, CoFePdB, CoPtN, CoPdN, FePtN, FePdN, CoFePtN, CoFePdN, CoPtBN, CoPdBN, FePtBN, FePdBN, CoFePtBN, CoFePdB, CoFeN, and CoFeBN.

28. The magnetic memory device of claim 23, wherein the magnetization reinforcement layer fixes a magnetization direction of the fixed magnetic layer regardless of change in a magnetization direction of the free magnetic layer.
